(19) United States
(12) Patent Application Publication
(10) Pub. No.: US 2016/0343885 A1
(43) Pub. Date: Nov. 24, 2016

(54) PHOTOELECTRIC CONVERSION DEVICE

(71) Applicant: SHARP KABUSHIKI KAISHA, Sakai City (JP)

(72) Inventors: Yoshiyuki NASUNO, Sakai City (JP); Kazuhito NISHIMURA, Sakai City (JP); Takayuki ISAKA, Sakai City (JP); Shinya HONDA, Sakai City (JP)

(21) Appl. No.: 15/115,011

(22) PCT Filed: Nov. 21, 2014
(86) PCT No.: PCT/JP2014/080839

§ 371 Date: Jul. 28, 2016

(30) Foreign Application Priority Data
Jan. 30, 2014 (JP) 2014-015309

(51) Int. Cl. H01L 31/0216; H01L 31/0224

(52) U.S. Cl. CPC H01L 31/02168; H01L 31/022425

(57) ABSTRACT

Provided is a photoelectric conversion device with an excellent conversion efficiency in which a series resistance between a semiconductor substrate and an electrode is reduced. The photoelectric conversion device includes a semiconductor substrate; a first conductivity region formed on the semiconductor substrate; and an electrode electrically connected to the first conductivity region, in which the first conductivity region includes an electrode region which faces the electrode, and crystal defects in the semiconductor substrate which faces the electrode region.

### TECHNICAL FIELD

The present invention relates to a photoelectric conversion device.

### BACKGROUND ART

Expectations of photoelectric conversion devices which directly convert solar light energy to electrical energy as next generation energy sources are rapidly increasing in recent years, in particular from the viewpoint of global environmental problems. Although a compound semiconductor, an organic material, or the like has been used as a material for a photoelectric conversion device, presently, silicon crystals are widely used. In the currently most commonly produced and sold photoelectric conversion devices, n-electrodes are provided on the light receiving surface which receives solar light and p-electrodes are provided on the rear surface which is the opposite surface to the light receiving surface. Although the n-electrodes provided on the light receiving surface side are necessary in order to extract current obtained by photoelectric conversion, when the electrode area is large, the conversion efficiency is lowered because solar light is not incident on the substrate where the n-electrodes are formed, due to obstruction by the n-electrodes. Such loss of conversion efficiency due to the electrodes on the light receiving surface side is referred to as shadow loss.

A high conversion efficiency can theoretically be realized in a rear surface electrode-type photoelectric conversion device having no electrodes on the light receiving surface because shadow loss due to the electrodes is eliminated and it is possible to receive substantially 100% of the incident solar light in the photoelectric conversion device. Examples of such rear surface-type photoelectric conversion devices are provided in Japanese Unexamined Patent Application Publication No. 2007-19259.

FIG. 11 is a schematic cross-sectional view illustrating the structure of a rear surface electrode-type photoelectric conversion device of the related art. High concentration p-type doping regions 52 and high concentration n-type doping regions 53 are alternately provided on the rear surface of a semiconductor substrate 50. A passivation film 51 formed of silicon oxide film, a silicon nitride film, or the like is formed on the surface of the semiconductor substrate 50, and surface recombination is thereby suppressed. P-electrode 54 and n-electrode 55 are connected to the high concentration p-type doping region 52 and the high concentration n-type doping region 53, respectively, through the p region contact hole 56 and the n region contact hole 57 provided on the rear surface, respectively, and electric current obtained by photoelectric conversion is extracted. The passivation film 51 on the light receiving surface also functions as an anti-reflection film. As is illustrated in FIG. 11, the p-type doping region, the n-type doping region, the p-electrode, and the n-electrode are all formed on the rear surface, there is nothing obstructing the light on the light receiving surface, and it is possible to receive substantially 100% of the solar light.

In the above-described related art example, although the p-electrode and the n-electrode are in direct contact with the semiconductor substrate, the improvements in the open-circuit voltage Voc and improvements in the efficiency are obtained by forming a so-called contact passivation structure in which a passivation film is further disposed between the metal electrode portions and the semiconductor substrate (metal electrode/passivation film/semiconductor layer), and recombination of carriers being reduced as far as possible on the semiconductor substrate as the method of further increasing the efficiency of the photoelectric conversion device. In this case, the film thickness of the passivation film has to be made thinner in order for a sufficient tunnel current to flow. According to Reference Document 1 (Dimitri Zielke, Physica Statuts Solidi, Rapid Research Letters Volume 5, Issue 8, pages 298-300), when the thickness of the passivation film on the doping region becomes greater than 2 nm, the series resistance increases.

### CITATION LIST

### Patent Literature

PTL 1: Japanese Unexamined Patent Application Publication No. 2007-19259

### Non Patent Literature

NPL 1: Dimitri Zielke, Physica Statuts Solidi, Rapid Research Letters Volume 5, Issue 8, pages 298-300

### SUMMARY OF INVENTION

### Technical Problem

However, in the contact passivation structure of the above-described photoelectric conversion device, it is difficult to resolve the conflicting problems of the series resistance increasing when the passivation layer film thickness increases, and the carrier recombination increasing when the passivation layer film thickness is reduced. Even in a photoelectric conversion device in which the p-electrode and the n-electrode are in direct contact with the semiconductor substrate, series resistance is present in the contact hole portion and a lowering of the FF is present. In this way, the series resistance between the semiconductor substrate and the electrode is a cause of a lowering of the conversion efficiency in the photoelectric conversion device of the related art.

The invention is conceived in consideration of the above, and an object thereof is to obtain a photoelectric conversion device in which the series resistance between the semiconductor substrate and the electrodes is reduced and which has a high conversion efficiency.

### Solution to Problem

According to an aspect of the invention, there is provided a photoelectric conversion device including a semiconductor substrate; a first conductivity region formed on the semiconductor substrate; and an electrode electrically connected to the first conductivity region, in which the first conductivity region includes an electrode region which faces the electrode, and crystal defects in the electrode region.

The photoelectric conversion device according to the aspect of the invention further includes a dielectric layer formed on the semiconductor substrate, in which the first conductivity region is provided on the dielectric layer.

In the photoelectric conversion device according to the aspect of the invention, the first conductivity region includes a non-electrode region other than the electrode region, and a first conductivity impurity concentration of the electrode region is higher than the first conductivity impurity concentration of the non-electrode region.

In the photoelectric conversion device according to the aspect of the invention, the first conductivity region includes a non-electrode region other than the electrode region, and a surface density of crystal defects in the electrode region is higher than a surface density of crystal defects in the non-electrode region.

In the photoelectric conversion device according to the aspect of the invention, the dielectric layer is formed of a first dielectric layer and a second dielectric layer formed on the first dielectric layer, and either of the first dielectric layer or the second dielectric layer is disposed between the first conductivity region and the electrode.

In the photoelectric conversion device according to the aspect of the invention, the surface density of the crystal defects is 550/cm² or more and 100,000/cm² or less.

In the photoelectric conversion device of the aspect of the invention, the thickness of the dielectric layer is 0.1 nm or more and 4.5 nm or less.

### Advantageous Effects of Invention

According to the invention, since the series resistance component between the semiconductor substrate and the electrode can be reduced, the conversion efficiency of the photoelectric conversion device can be improved.

### BRIEF DESCRIPTION OF DRAWINGS

FIG. 1 is a schematic cross-sectional view of a photoelectric conversion device of the invention.

FIG. 2 is a partially enlarged view of the photoelectric conversion device of the invention.

FIG. 3 is a table illustrating the relationship between the density of defects in the crystal defect region and the cell characteristics.

FIG. 4 is a graph illustrating the relationship between the defect density and the conversion efficiency.

FIG. 5 shows cross-sectional views illustrating crystal defects.

FIG. 6 shows tables describing the relationship between the dielectric layer thickness and the characteristics of the photoelectric conversion device.

FIG. 7 illustrates schematic cross-sectional views of the photoelectric conversion device of a second embodiment of the invention.

FIG. 8 is a schematic cross-sectional view of the photoelectric conversion device of a third embodiment of the invention.

FIG. 9 is a schematic cross-sectional view of the photoelectric conversion device of a fourth embodiment of the invention.

FIG. 10 is a table comparing the conversion efficiencies of photoelectric conversion devices with different openings.

FIG. 11 is a schematic cross-sectional view illustrating a structure of a photoelectric conversion device of the related art.

### DESCRIPTION OF EMBODIMENTS

Embodiments of the invention will be described below with reference to the figures. In the following description, the same references are applied to the same components. The names and functions thereof are also the same. Accordingly, a detailed description thereof will not be repeated.

### Embodiment 1

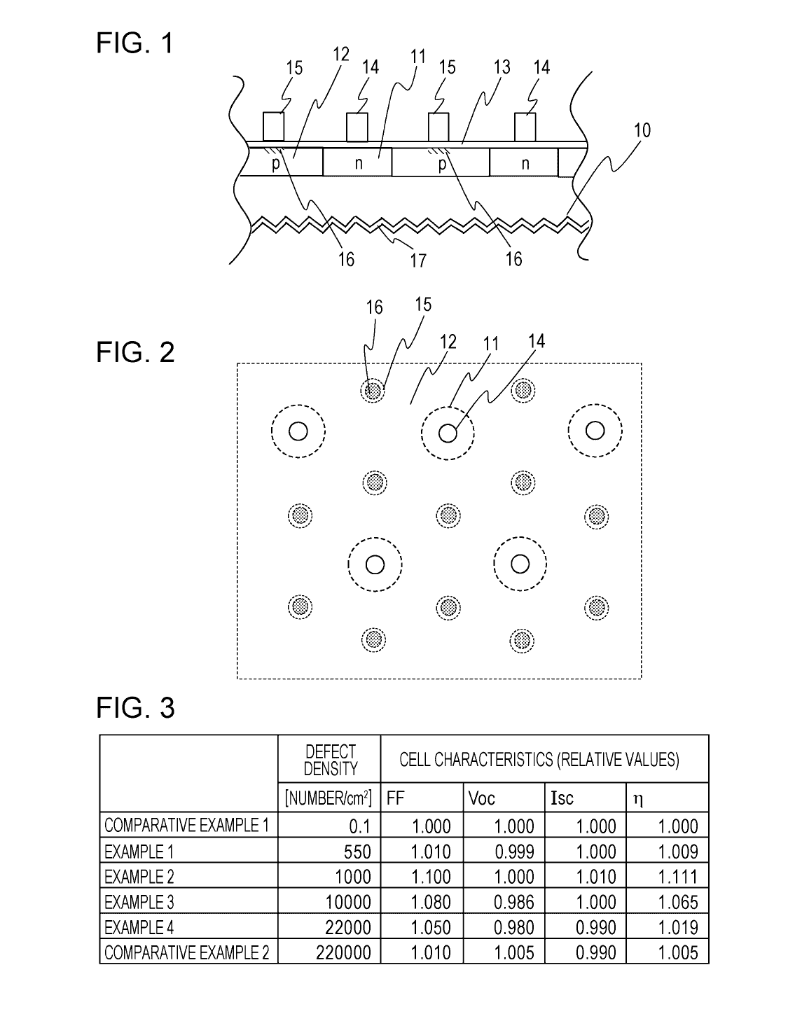

FIG. 1 is a schematic cross-sectional view of a photoelectric conversion device of the invention. In FIG. 1, an n-type region 11 doped with an n-type dopant which is a first conductivity type, such as phosphorous (P), and a p-type region 12 doped with a p-type dopant which is a second conductivity type, such as boron (B) are formed on the surface on the opposite side to the light receiving surface of the n-type silicon substrate 10. It is possible to form the n-type region 11 and the p-type region 12 on the surface of the opposite side to the light receiving surface of the n-type silicon substrate 10 by thermal diffusion of the dopant and ion injection of dopant ions.

A dielectric layer 13 is formed on the n-type region 11 and the p-type region 12. It is possible to use silicon oxide, silicon nitride, silicon oxynitride, aluminum oxide, and the like as the dielectric layer, and it is possible to form the dielectric layer using a plasma CVD method, an atomic layer deposition (ALD) method, or the like. Herein, silicon oxide is used as the dielectric layer.

An n-electrode 14 is provided on the n-type region 11 with the dielectric layer 13 interposed. Although the n-type region 11 is not in contact with the n-electrode 14 in a portion where the n-electrode 14 faces the n-type region, because the dielectric layer 13 is thin, the n-type region 11 and the n-electrode 14 are electrically connected through the tunnel effect.

A p-electrode 15 is provided on the p-type region 12 with the dielectric layer 13 interposed. Although the p-type region 12 is not in contact with the p-electrode 15, because the dielectric layer 13 is thin in a portion where the p-type region 12 faces the p-electrode 15, the p-type region 12 and the p-electrode 15 are electrically connected through the tunnel effect.

A crystal defect region 16 is further formed in the vicinity of the interface with the dielectric layer 13 in the portion in which the p-type region 12 faces the p-electrode 15.

By forming the crystal defect region 16 which includes crystal defects in the portion in which the p-type region 12 faces the p-electrode 15, because the tunnel current easily flows via the thin dielectric layer by a space charge being guided to the interface between the p-type region and the dielectric layer, it is possible to reduce the series resistance of the dielectric layer 13. It is not necessary that the crystal defect region 16 completely match the portion at which the p-type region 12 faces the p-electrode 15.

The light receiving surface side of the n-type silicon substrate 10 is subjected to texture processing, and an anti-reflection film 17 formed of silicon nitride, titanium oxide, or the like is formed. The anti-reflection film 17 has a passivation function on the light receiving surface of the n-type silicon substrate 10.

FIG. 2 is a partially enlarged view in which the photoelectric conversion device of the invention is viewed from the electrode side, and is an enlarged view of a portion of the electrode forming surface of the photoelectric conversion device 1. The n-type region 11 is a circular region on the n-type silicon substrate 10 and is below the dielectric layer 13, the interior of the circle has a higher n-type dopant concentration than the n-type silicon substrate 10. The n-electrode 14 is above the dielectric layer 13 and is positioned substantially in the center of the circular n-type region 11.

The p-type region 12 is formed on the n-type silicon substrate 10 and is formed to encompass the n-type region 11. The circular p-electrode 15 is provided on the p-type region 12 and above the dielectric layer 13. The crystal defect region 16 is provided in the p-type region 12 directly below the p-electrode 15. Although the p-electrode 15 and the crystal defect region 16 may be formed to exactly overlap when viewed from the normal direction of the silicon substrate, by forming the crystal defect region 16 to be smaller than the p-electrode 15, as illustrated in FIG. 2, it is possible for the passivation properties of the n-type silicon substrate below the p-electrode 15 to be improved, and is preferable.

The n-type region 11 and the p-type region 12 are formed by the n-type dopant, such as phosphorous, and the p-type dopant, such as boron, being dispersed, respectively, in the surface of the opposite side to the light receiving surface of the n-type silicon substrate 10. Through ion injection of the p-type dopant, such as boron, in the crystal defect region 16, the first conductivity type impurity concentration (boron concentration) is further increased, and the crystal defects are introduced in the surface of the p-type region on the silicon substrate with the ion injection region. The impurity concentration (boron concentration) in the crystal defect region 16 is approximately 5×10¹⁸ to 2×10²⁰ atoms/cm³. The impurity concentration (boron concentration) in the p-type region 12 outside the crystal defect region 16 is approximately 1×10¹⁷ to 1×10¹⁹ atoms/cm³. That is, the boron concentration of the crystal defect region 16 becomes higher than the boron concentration outside the crystal defect region.

As a result, the first conductivity type impurity concentration in the first conductivity type region in which crystal defects are included is made higher than the first conductivity type impurity concentration of the second region which is a region outside the first conductivity type region in which crystal defects are included.

The surface density of crystal defects in the first conductivity type region becomes higher than the surface density of crystal defects in the second region.

Whereas the passivation effect is increased while suppressing the surface impurity concentration in the region not directly below the electrode from the n-type region and the p-type region to be low, it is possible to obtain a high output by using a structure in which the region directly below the electrode is doped with impurities to a high concentration, thereby lowering the resistance loss.

The p-type dopant is selected as the element which is ion injected in order to form the p-type region, in a case where an n-type silicon substrate is used in order to increase output. Although high temperature annealing at 1050° C. or more is usually necessary in the ion injection of boron as the thermal processing in order to remove defects due to the ion injection, when annealing is performed at high temperatures, the bulk lifetime of the silicon substrate is greatly decreased due to the generation of defects due to impurities other than the dopant.

The selective emitter structure is formed by forming a p-type region on the rear surface with a diffusion method, and then, ion injecting boron only in the p-type region at the portion facing the electrode and which is to be created as the crystal defect region, and doping to a high concentration. As a result, crystal defects due to the ion injection process are formed in the p-type region subjected to ion injection. However, crystal defects due to the ion injection process are not formed in the p-type region not subjected to ion injection. In this state, when annealing is performed while suppressing the annealing temperature to a low temperature of approximately 900 to 950° C., the bulk lifetime of the entire silicon substrate is not impaired. Because only the p-type region directly below the p-electrode is subjected to high concentration doping by ion injection, crystal defects remain only in this portion. In this way, the crystal defect region is formed.

The surface density of crystal defects in the crystal defect region 16 is compared to the region outside the crystal defect region 16 on the same surface of the silicon substrate, and crystal defects may be introduced to relatively increase the surface density of crystal defects. More specifically, for example, in a case where the crystal defect surface density in the region outside the crystal defect region 16 on the same surface of the silicon substrate is less than 550/cm², crystal defects may be introduced so that the surface density of crystal defects in the region outside the crystal defect region 16 on the same surface of the silicon substrate becomes 550/cm² or more. That is, it is possible to reduce the series resistance Rs of the photoelectric conversion device by a space charge being introduced at the interface between the crystal defect region and the dielectric layer and to realize improvements in the FF and the conversion efficiency by making the surface density of crystal defects higher than that of the peripheral regions of the crystal defect region 16. The surface density D of crystal defects is calculated in the following manner. When a cross-section of the crystal defect region 16 is observed by cross-sectional TEM, the crystal defects are observed as dislocation lines in the crystal lattice. In a case where the number of crystal defects observed in a given cross-section is N (number) and the observed width of the crystal defect region 16 is L (cm), it is possible to calculate D=(N/L)² [number]/cm²]. The reason for this is thought to be that because anisotropy related to the formation of the crystal defects is not present, the crystal defect linear surface density becomes N/L in any direction in a case where TEM observation is carried out at two orthogonal cross-sections. Accordingly, it is possible for the surface density to be derived as a square of N/L, that is, the crystal defect linear surface density. In this way, the surface density of crystal defects is calculated from a cross-sectional TEM image. In a case where it is possible for crystal defects to be confirmed by observation with TEM from above the wafer surface, the surface density of crystal defects may be directly calculated from the observation image of the wafer surface.

Although oxygen stacking defects arise in the p-type region directly below the electrode through ion injection of boron, these move to the silicon substrate surface due to the annealing process and are lost in the silicon substrate surface. At this time, the time of the annealing process is adjusted, and defects remain in the semiconductor substrate surface. It is possible to realize the density of crystal defects by controlling the time of the annealing process. By crystal defects remaining at a predetermined density, it is possible to obtain a passivation effect while realizing a cell structure with lowered series resistance.

It should be noted that the n-type dopant, such as phosphorous, also directly below the n-electrode may be introduced by ion injection rather than diffusion. In this case, since it is difficult for crystal defects to remain compared to a case of ion injection of boron following the process of subjecting the surface of the silicon substrate to amorphizing and recrystallization with an annealing process, the crystal defect region is not formed directly below the n-electrode.

FIG. 3 is a table illustrating the relationship between the density of defects in the crystal defect region and the cell characteristics, in which the defect density in the crystal defect region 16 in FIG. 1 is changed and the cell characteristics are measured. In each example and the comparative examples, the highest arrival point of the cell characteristics are indicated by relative values. The fill factor FF, the open-circuit voltage Voc, the short-circuit current Isc, and the conversion efficiency η are relative values with the characteristics of Comparative Example 1 as a reference. There are almost no crystal defects directly below the p-electrode of Comparative Example 1. Meanwhile, for Examples 1 to 4 and Comparative Example 2, the annealing process after ion injection is controlled and crystal defects are provided in the p-type region directly below the electrode, and the number of crystal defects in the crystal defect region is changed according to the annealing conditions.

Examples 1 to 4 have a conversion efficiency η improved by 1% or more compared to Comparative Example 1 without crystal defects. Meanwhile, the crystal defects in Comparative Example 2 are excessively numerous, and recombination of the carrier increases, thereby the conversion efficiency does not improve.

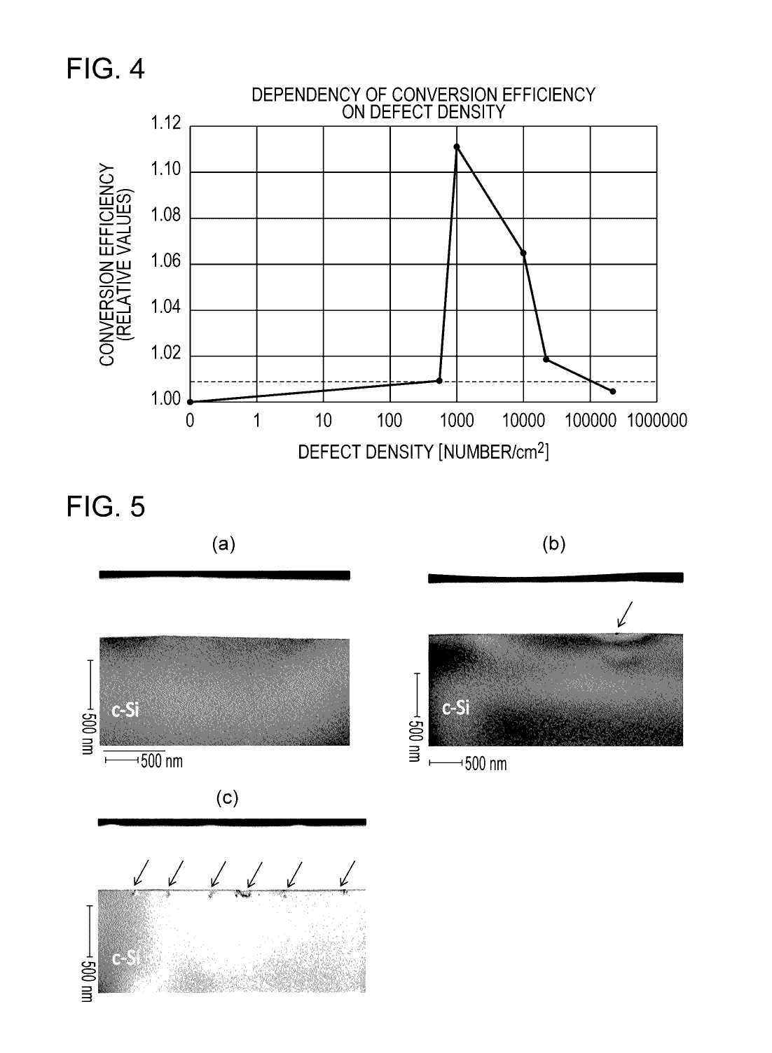

FIG. 4 is a diagram illustrating the relationship between the defect density and the conversion efficiency, and the relationship between the defect density and the conversion efficiency η in Table 1 is illustrated by a graph. The conversion efficiency η is a relative value when not having crystal defects is 1. The line on which the conversion efficiency η is improved by 1% or more (becomes 1.01 times or more) over the Comparative Example 1 in which defects are not formed is illustrated with a dotted line. According to Table 1, it is found that the conversion efficiency improves by a relative value of 1% or more compared to the comparative example without a crystal defect region with the crystal defects in a range of 550/cm² or more and 100,000/cm² or less.

FIG. 5 shows cross-sectional views illustrating crystal defects, which are photographs of a cross-section directly below the p-electrode taken by a transmission electron microscope (TEM). The location of the crystal defects is indicated by the arrow. FIG. 5(a) is a cross-sectional photograph of Comparative Example 1, without crystal defects in the surface of the silicon substrate. FIG. 5(b) is one cross-sectional photograph of Example 1. It is determined that the defect density of crystal defects in Example 1 is approximately 550/cm² according to a plurality of TEM observation images. FIG. 5(c) is a cross-sectional photograph of Example 2 and is an example in which still more crystal defects remain. It is determined that the defect density of crystal defects is approximately 1000/cm² according to a plurality of TEM observation images.

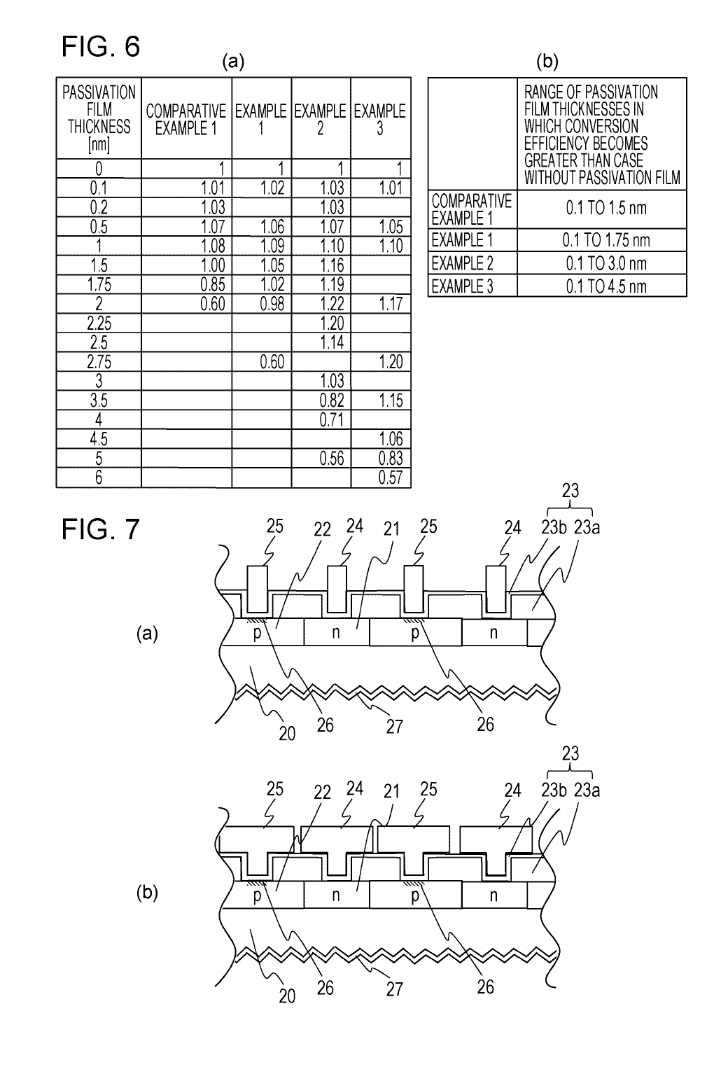

FIG. 6 shows tables describing the relationship between the dielectric layer thickness and the characteristics of the photoelectric conversion device. FIG. 6(a) illustrates the relationship between the thickness of the dielectric layer and the conversion efficiency η in Comparative Example 1 and Examples 1 to 3. FIG. 6(b) illustrates the range of dielectric layer thickness in which the conversion efficiency η increases compared to when a dielectric layer is not present in each of Comparative Example 1, and Examples 1 to 3. The numerical values are relative values with the conversion efficiency in cases where the dielectric layer in Comparative Example 1 and Examples 1 to 3 is not present as a reference, respectively. Accordingly, as long as the numerical value is one or more, the conversion efficiency η is illustrated as high, compared to in cases without the dielectric layer in each example.

Although the range of film thicknesses in which there is an effect of efficiency improvements due to the dielectric layer is 0.1 nm to 1.5 nm in Comparative Example 1 without crystal defects, the range of film thicknesses with the effect of the dielectric layer increases in all of the examples provided with a crystal defect region. In particular, in the case of Example 3, it is found that the conversion efficiency is improved over those without the dielectric layer directly below the electrode over a wide range in which the thickness of the dielectric layer is from 0.1 nm or more and 4.5 nm or less.

The series resistance Rs between the electrode and the dielectric layer is lowered, and the range of thickness of the dielectric layer in which the efficiency is improved over a case without the dielectric layer becomes larger by forming the crystal defect region. That is, the range of permissible layer thickness of the dielectric layer is wide. The maximum value of the efficiency when the layer thickness is suitably controlled also increases.

As the defect density introduced to the conductivity layer directly below the electrode increases, the range of film thickness of the dielectric layer in which the conversion efficiency increases widens to the larger side. This is because it is possible to achieve both improvements in the open-circuit voltage Voc and decreases in series resistance Rs as the passivation effect, since it is difficult to increase the series resistance Rs even if the dielectric layer is thick because the series resistance Rs between the electrode and the conductivity layer is decreased due to the increase in the introduction amount of defects.

Although, in a case where the range of film thicknesses of the dielectric layer in which the conversion efficiency improves is narrow as in Comparative Example 1, when the thickness of the dielectric layer directly below the electrode is uneven, the narrowness becomes a cause of the lowering of the conversion efficiency and an increase in unevenness, and, in a case where the range film thickness of the dielectric layer in which the conversion efficiency improves is wide, it is possible to decrease the influence that the thickness of the dielectric layer exerts on the conversion efficiency. As a result, since a high conversion efficiency stabilized with respect to unevenness in the production conditions is obtained, it is possible to realize improvements in the average conversion efficiency and the production yield during production.

Although an n-type semiconductor substrate is used in the examples, a p-type semiconductor substrate may be used.

### Embodiment 2

FIG. 7 illustrates schematic cross-sectional views of the photoelectric conversion device of the second embodiment of the invention. Configurations other than the dielectric layer and the electrode are the same as the photoelectric conversion device illustrated in FIG. 1. In FIG. 7(a), an n-type region 21 doped with an n-type dopant such as phosphorous (P), and a p-type region 22 doped with a p-type dopant such as boron (B) are formed on the opposite side to the light receiving surface of the n-type silicon substrate 20. A dielectric layer 23 of silicon oxide or silicon nitride is formed on the n-type region 21 and the p-type region 22.

An n-electrode 24 is provided on the n-type region 11 with the dielectric layer 23 interposed. A p-electrode 25 is provided on the p-type region 22 with the dielectric layer 23 interposed. The thickness of the dielectric layer 23 directly below the n-electrode 24 and the p-electrode 25 becomes thinner than in other portions. Although the dielectric layer 23 is formed of two layers having a first dielectric layer 23a and a second dielectric layer 23b, only the second dielectric layer 23b is present in the dielectric layer directly below the electrode in which the p-type region 22 faces the p-electrode 25, and the thickness becomes thinner.

Such a structure as above is formed by the process illustrated below. First, after the n-type region 21 and the p-type region 22, the crystal defect region 26 is formed on the p-type region on the opposite side to the light receiving surface of the n-type silicon substrate 20. Subsequently, the first dielectric layer 23a is formed with a thickness of approximately 70 to 80 nm. Next, openings that reach the n-type regions or the p-type regions are formed at positions the n-electrode 24 or the p-electrode 25 are formed. Next, it is possible for the dielectric layer to be prepared by forming the second dielectric layer 23b is formed with a thickness of 0.5 to 1.5 nm, and next forming the n-electrodes 24 and p-electrodes 25 on the second dielectric layer 23b.

In this way, by forming the first dielectric layer 23a and the second dielectric layer 23b, it is possible for the n-electrodes 24 and the p-electrodes 25 to face the n-type regions and the p-type regions, respectively, at a short distance with the second dielectric layer which is formed thin interposed in the opening in the first dielectric layer which is formed thick. Thereby, it is possible to mitigate the series resistance between each electrode and conductivity region. Furthermore, since it is possible to thicken the dielectric layer on the n-type region 21 and the p-type region 22 which the n-electrode 24 and the p-electrode 25 do not face, it is possible to increase passivation effect as a result, thereby obtaining a high Voc and photoelectric conversion efficiency.

The crystal defect region 26 is formed in the p-type region 22 directly below the p-electrode 25 in the vicinity of the interface with the dielectric layer 23. Thereby, it is possible for the series resistance of the dielectric layer 23 to be reduced because a tunnel current easily flows via the thin dielectric layer by the space charge being introduced to the interface between the p-type region and the dielectric layer.

A fine unevenness is formed on the surface on the opposite side to the light receiving surface of the n-type silicon substrate 20 due to crystal defects being introduced. The height of the unevenness is 0.5 to 5 nm. In this way, by forming the fine unevenness, since electrical conductivity between the n-electrode 24 and the n-type region 11 is easily achieved via the second dielectric layer 23b in the opening in the first dielectric layer 23a, it is possible to reduce the series resistance and improve the FF and the conversion efficiency.

The light receiving surface side of the n-type silicon substrate 20 is subjected to texture processing, and an anti-reflection film 27 formed of silicon nitride, titanium oxide, or the like is formed. The anti-reflection film 27 also has a passivation function on the light receiving surface of the silicon substrate.

As illustrated in FIG. 7(b), the n-electrode 24′ or the p-electrode 25′ may also be formed on the portions outside the opening in the dielectric layer 23a, that is, on the dielectric layer in portions other in which the electrode faces the n-type region or p-type region. In this case, enough of a gap to not short circuit is provided between the p-electrode 24′ and the n-electrode 25′.

### Embodiment 3

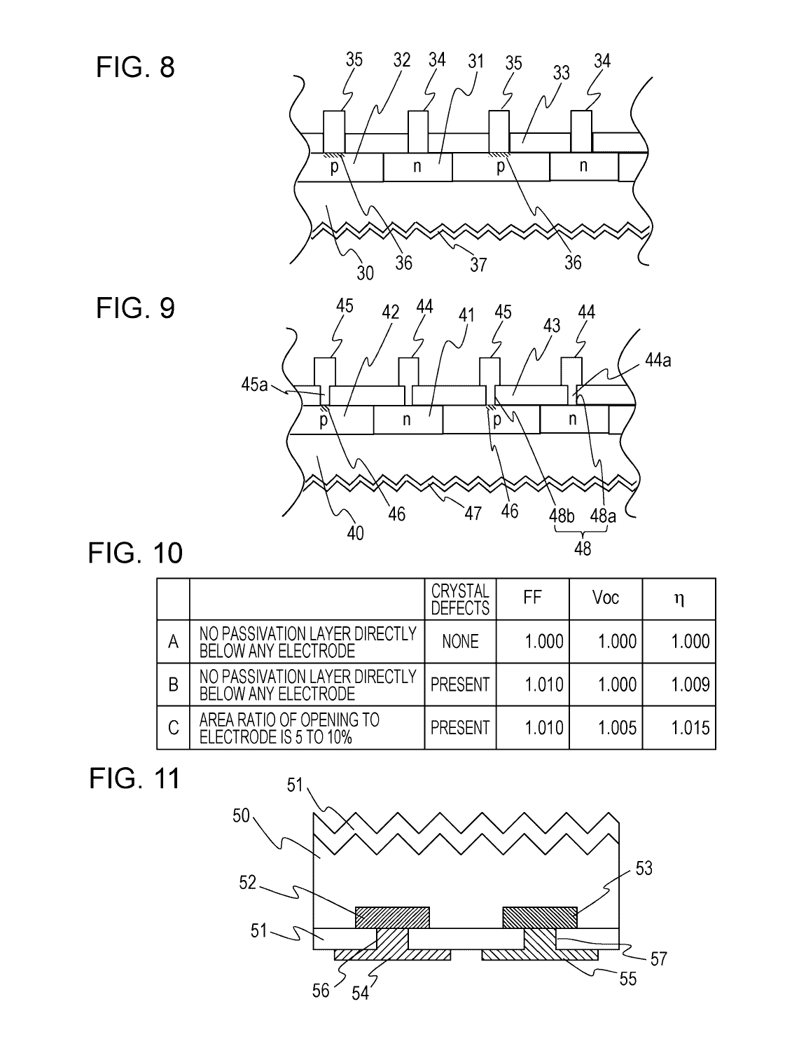

FIG. 8 is a schematic cross-sectional view of the photoelectric conversion device of the third embodiment of the invention. Configurations other than the dielectric layer and the electrode are the same as the photoelectric conversion device illustrated in FIG. 1.

In FIG. 8, an n-type region 31 doped with an n-type dopant such as phosphorous (P), and a p-type region 32 doped with a p-type dopant such as boron (B) are formed on the opposite side to the light receiving surface of the n-type silicon substrate 30. A dielectric layer 33 of silicon oxide or silicon nitride is formed on the n-type region 31 and the p-type region 32. An opening is provided in the dielectric layer 33, and the n-electrode 34 is provided in the opening on the n-type region 31. The p-electrode 35 is provided on the opening on the p-type region 32. The difference between the Embodiments 1 and 2 in including a region in which each conductivity region and electrode come in direct contact without the dielectric layer interposed.

A crystal defect region 36 is further formed in the vicinity of the interface with the p-electrode 35 in the portion in which the p-type region 32 faces the p-electrode 35. It is possible to reduce the series resistance of the interface between the p-type region 32 and the p-electrode 35 in order for the current to easily flow via the defects by forming the crystal defect region 36.

It should be noted that, even if the crystal defect region is formed and the series resistance is reduced, because the effect of the crystal defects promoting carrier recombination becomes greater in a structure without the dielectric layer on the surface of the opposite side to the light receiving surface, the conversion efficiency is instead reduced. Thus, it is necessary for the portion outside the region in which the electrodes and each conductivity region come into direct contact in the surface of the opposite side to the light receiving surface to be substantially covered by a dielectric layer with a suitable thickness.

The light receiving surface side of the n-type silicon substrate 30 is subjected to texture processing, and an anti-reflection film 37 formed of silicon nitride, titanium oxide, or the like is formed. The anti-reflection film 37 also has a passivation function on the light receiving surface of the silicon substrate.

### Embodiment 4

FIG. 9 is a schematic cross-sectional view of the photoelectric conversion device of the fourth embodiment of the invention. Configurations other than the dielectric layer, the electrode, and the crystal defect region are the same as the photoelectric conversion device illustrated in FIG. 1.

In FIG. 9, an n-type region 41 doped with an n-type dopant such as phosphorous (P), and a p-type region 42 doped with a p-type dopant such as boron (B) are formed on the surface on the opposite side to the light receiving surface of the n-type silicon substrate 40. A dielectric layer 43 of silicon oxide or silicon nitride is formed on the n-type region 41 and the p-type region 42. An opening 48 is provided in the dielectric layer 43, and the n-electrode 44 is provided at a position corresponding to in the opening 48a in the n-type region 41. The p-electrode 45 is provided at a position corresponding to the opening 48b in the p-type region 42.

The opening 48a becomes smaller than a given n-electrode 44 on the dielectric layer 43, and the n-electrode 44a which is the lower portion of the n-electrode 44 becomes finer according to the shape of the opening 48a. The opening 48b becomes smaller than a given p-electrode 45 on the dielectric layer 43, and the p-electrode 45a which is the lower portion of the p-electrode 45 becomes finer according to the shape of the opening 48b. The crystal defect region 46 is a portion in which the p-type region faces the opening, and the p-type region 42 is present in a portion facing the p-electrode 45.

The light receiving surface side of the n-type silicon substrate 40 is subjected to texture processing, and an anti-reflection film 47 formed of silicon nitride, titanium oxide, or the like is formed. The anti-reflection film 47 also has a passivation function on the light receiving surface of the silicon substrate.

FIG. 10 is a table comparing the conversion efficiencies of photoelectric conversion devices in which the areas of the openings differ. The conversion efficiency η in photoelectric conversion device provided with the crystal defect region 46 becomes greater compared to the photoelectric conversion device of the related art without a crystal defect region. It is further found that the photoelectric conversion device, in which an area ratio of the opening to the electrode area on the dielectric layer is reduced to approximately 5 to 10%, has a higher conversion efficiency η. In the drawing, the fill factor FF, the open-circuit voltage Voc, the conversion efficiency η are relative values when the structure of the related art is 1.

Since the series resistance is reduced by the crystal defect region 46, it is possible to make the opening 48 smaller. Since the proportion occupied by the dielectric layer 43 is increased by reducing the opening 48, it is possible for the Voc, FF, and conversion efficiency to be improved because the passivation effect is improved.

It should be understood that the embodiments disclosed herein are illustrative and non-restrictive in every respect. The scope of the invention is defined by the terms of the claims, rather than the above description, and is intended to include any modifications within the scope and meaning equivalent to the terms of the claims.

### REFERENCE SIGNS LIST

10, 20, 30, 40 n-type silicon substrate

11, 21, 31, 41 n-type region

12, 22, 32, 42 p-type region

13, 23, 33, 43 dielectric layer

14, 24, 24′, 34, 44, 44a n-electrode

15, 25, 25′, 35, 45, 45a p-electrode

16, 26, 36, 46 crystal defect region

17, 27, 37, 47 anti-reflection film

23a first dielectric layer

23b second dielectric layer

48, 48a, 48b opening

1. A photoelectric conversion device comprising:
a semiconductor substrate;
a first conductivity region formed on the semiconductor substrate; and
an electrode electrically connected to the first conductivity region,
wherein the first conductivity region includes an electrode region which faces the electrode, and crystal defects in the electrode region.

2. The photoelectric conversion device according to claim 1, further comprising:
a dielectric layer formed on the semiconductor substrate,
wherein the first conductivity region is provided on the dielectric layer.

3. The photoelectric conversion device according to claim 1,
wherein the first conductivity region includes a non-electrode region other than the electrode region, and
a first conductivity impurity concentration of the electrode region is higher than a first conductivity impurity concentration of the non-electrode region.

4. The photoelectric conversion device according to claim 1,
wherein the first conductivity region includes a non-electrode region other than the electrode region, and
a surface density of crystal defects in the electrode region is higher than a surface density of crystal defects in the non-electrode region.

5. The photoelectric conversion device according to claim 1,
wherein the dielectric layer is formed of a first dielectric layer and a second dielectric layer formed on the first dielectric layer, and
either of the first dielectric layer or the second dielectric layer is disposed between the first conductivity region and the electrode.

6. The photoelectric conversion device according to claim 1,
wherein the surface density of the crystal defects is 550/cm² or more and 100,000/cm² or less.

7. The photoelectric conversion device according to claim 1,
wherein a thickness of the dielectric layer is 0.1 nm or more and 4.5 nm or less.
